(19) United States
(12) Patent Application Publication
(10) Pub. No.: US 2014/0082496 A1
(43) Pub. Date: Mar. 20, 2014

(54) APPARATUS AND METHOD FOR CONTROLLING VOLUME

(71) Applicant: Pantech Co., Ltd., Seoul (KR)

(72) Inventors: Suk-Hyen JUNG, Seoul (KR); Min-Woo Han, Incheon-si (KR)

(73) Assignee: Pantech Co., Ltd., Seoul (KR)

(21) Appl. No.: 14/028,593

(22) Filed: Sep. 17, 2013

(30) Foreign Application Priority Data
Sep. 19, 2012 (KR) 10-2012-0104112

(51) Int. Cl. H03G 3/02

(52) U.S. Cl. CPC H03G 3/02
USPC 715/716; 381/109

(57) ABSTRACT

An apparatus and method for controlling volume in a terminal adjust the volume of applications in the terminal without adjusting a main volume of the terminal. The apparatus and method display the relative volume of applications and allow a user to adjust each application's volume. If a user adjusts the volume of an application to be greater than a main volume of the terminal, the application's volume may be set to the main volume of the terminal.

### CROSS-REFERENCE TO RELATED APPLICATION

This application claims priority from and the benefit under 35 U.S.C. §119(a) of Korean Patent Application No. 10-2012-0104112, filed on Sep. 19, 2012, which is incorporated by reference for all purposes as if fully set forth herein.

### BACKGROUND

1. Field

The following description relates to a technology for controlling volume of a terminal, and more particularly to an apparatus and a method for controlling volume of more than one application.

2. Discussion of the Background

With developments in software and hardware, various content are able to be concurrently executed in a terminal, such as a smart device, and multi-tasking processes are frequently performed in such terminals.

Generally, a terminal may include a physical key (hereinafter, referred to as a volume key) to control the volume thereof. However, such a volume key may be used to control the entire volume of a terminal. In other words, a volume key may control volume of all sound-reproducing application at once, but may not be able to control volume of two or more applications individually.

Therefore, if a user wishes to control volume of individual application, it may be necessary to pause a currently operating application, enter a setting environment of the application, and control the volume. If the user seeks to control volume of a plurality of applications, he or she may undergo the above burdensome step as many times as the number of applications. Furthermore, if an application has no menu for volume control, it may be impossible to control volume of the application.

### SUMMARY

Exemplary embodiments of the present invention provide an apparatus and method for controlling volume in a terminal, such that the volume level of an individual application in the terminal may be controlled without altering a main volume of the terminal.

Exemplary embodiments of present invention also provide an apparatus and method for controlling volume in a terminal in which the volume level of more than one application may be adjusted without adjusting a main volume level of the terminal.

Additional features of the invention will be set forth in the description which follows, and in part will be apparent from the description, or may be learned by practice of the invention.

An exemplary embodiment of the present invention discloses an apparatus to control volume, including: a volume level determining unit to determine the volume of an application; and a control unit to adjust the volume of the application, wherein a main volume of the apparatus is not changed if the application's volume is adjusted.

An exemplary embodiment of the present invention also discloses a method for controlling volume, the method including: searching for an application being executed in a terminal; determining the volume of the executed application; displaying the volume of the executed application; receiving an input to adjust the volume of the executed application; and adjusting the volume of the executed application.

An exemplary embodiment of the present invention also discloses a method for controlling volume, the method comprising: determining an application which is capable of outputting sound in a terminal; determining the set volume of the application; displaying the set volume of the application; receiving an input to adjust the set volume of the application independent of a main volume of the terminal; and storing the adjusted volume level of the application.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a configuration of an apparatus to control volume according to an exemplary embodiment of the present invention.

FIG. 2 is a flow chart illustrating a method for controlling volume according to an exemplary embodiment of the present invention.

FIG. 3A FIG. 3B, FIG. 3C, and FIG. 3D are diagrams illustrating examples of controlling volume according to an exemplary embodiment of the present invention.

FIG. 4 is a diagram illustrating a configuration of an apparatus to control volume according to an exemplary embodiment of the present invention.

FIG. 5 is a flow chart illustrating a method for controlling volume according to an exemplary embodiment of the present invention.

FIG. 6 is a diagram illustrating a screen of a list of applications and volume control bars displayed according to an exemplary embodiment of FIG. 4.

### DETAILED DESCRIPTION OF THE ILLUSTRATED EMBODIMENTS

Exemplary embodiments are described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements. Although features may be shown as separate, such features may be implemented together or individually. Further, although features may be illustrated in association with an exemplary embodiment, features for one or more exemplary embodiments may be combinable with features from one or more other exemplary embodiments

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

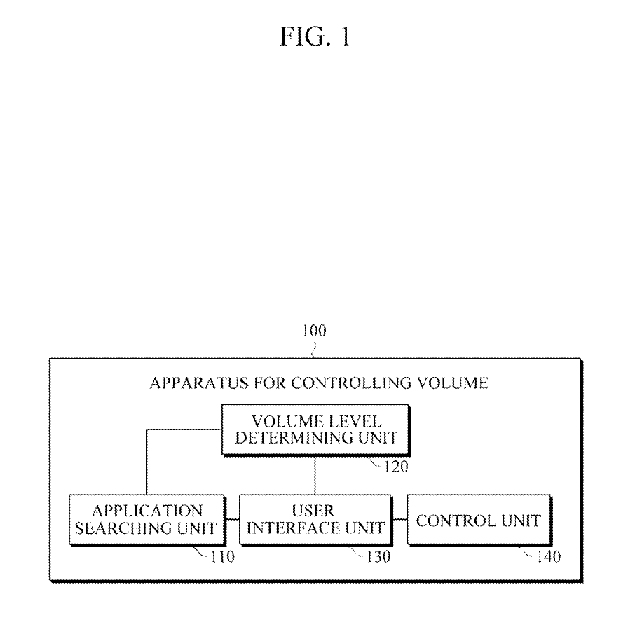

FIG. 1 is a configuration of an apparatus to control volume according to an exemplary embodiment of the present invention.

Referring to FIG. 1, the apparatus 100 to control volume includes an application searching unit 110, a volume level determining unit 120, a User Interface (UI) unit 130, and a control unit 140. The apparatus 100 may be disposed in and may control the volume of a terminal. The terminal may include a media volume, which may be maximum volume of the terminal at which the terminal may operate. The media volume may include a main volume of the terminal at which the terminal is set to operate. The terminal may be, for example, a mobile communication terminal, handheld, portable, tablet, laptop, desktop computer or communication device, or other apparatus, for controlling a volume of an application, and should not be construed in a limiting sense. Also, the terminal, and the units, modules, elements, devices and components of the terminals herein described, may include hardware and/or software, and can also include firmware, to perform various operations of the terminal including those for controlling volumes of applications, as described herein.

If a command to control volume of an application is received through a UI of the corresponding terminal, the application searching unit 110 may search for or determine an application which may support or utilize sound producing sources and is being executed at a time when the command is received. The volume of the application may be managed differently or separate from the main volume level or media volume of the terminal. A sound producing source may include any device which produces sound, such as a speaker, a bell, etc. The command may be received in various ways, including by clicking a reference key (for example, a volume key) of a terminal, touching a reference area on a touch screen of a terminal, performing a reference gesture in the proximity of a terminal, etc. However, the exemplary embodiments are not limited thereto, and any mechanism by which to receive commands may be utilized.

The volume level determining unit 120 may determine a relative volume level of the application which is found by the application searching unit 110. For example, the volume determining unit 120 may determine a relative volume level of each application with respect to a main volume level of the media volume or an absolute volume level may be determined.

The UI unit 130 may display the volume level of the application and the main volume level. The volume level of the application may be displayed in association with the application. If the volume level of the application is displayed in association with the application, the main volume level of the media volume may also be displayed by the UI unit 130. For example, if displaying a volume level determined by the volume level determining unit 120, the UI unit 130 may display the determined volume level of the application in a form of volume control bar, such as, a seekbar utilized in the Android operating system. However, the exemplary embodiments are not limited thereto, and the UI unit 130 may display the determined volume in any manner which conveys the volume level. If the application searching unit 110 fails to find or determine an application which may utilize or supports sound producing sources and which is being executed at a time when the command is received, the UI unit 130 may display the main volume level of the media volume.

The UI unit 130 may receive an input to control volume of an application. The UI unit 130 may receive the input to control volume through a UI. For example, the UI unit 130 may provide a UI in which the volume value determined by the volume level determining unit is displayed in a form of volume control bar. The volume control bar may be displayed in association with the corresponding application, for example, by displaying a pop-up window on a display screen of the terminal to receive an input.

The control unit 140 may adjust the volume of an application to be at a volume level which is input through the UI unit 130. The control unit 140 may adjust or determine the volume of each application which uses sound or a reference number of applications which use sound.

If the input volume level is greater than a main volume level of the media volume of the terminal when the input volume level is received through the UI unit 130, the control unit 140 may adjust or determine the volume of the corresponding application to be at the main volume level of the media volume, or lower than the main volume level, for example at a predetermined or set maximum volume level. However, exemplary embodiments are not limited thereto, and if the input volume level is greater than the main volume level of the media volume, the control unit may adjust or determine the main volume to be at the same level as the input volume level or higher.

For example, a media volume may range from level 0 to level 10 and a main volume level of the media volume may be set to level 6 when the volume level is input through the UI unit 130. If the volume level input through the UI unit 130 is level 8, the control unit 140 may adjust the volume of a corresponding application to be at level 6, i.e., the main volume level of the media volume, or lower. In other words, it may not be possible to adjust the volume of an application to be at a level greater than a main volume level of the media volume which is set at the time when the input volume level is received. However, exemplary embodiments are not limited thereto, and the UI unit 130 may adjust the main volume of the media volume according to an input volume level received for a reference application.

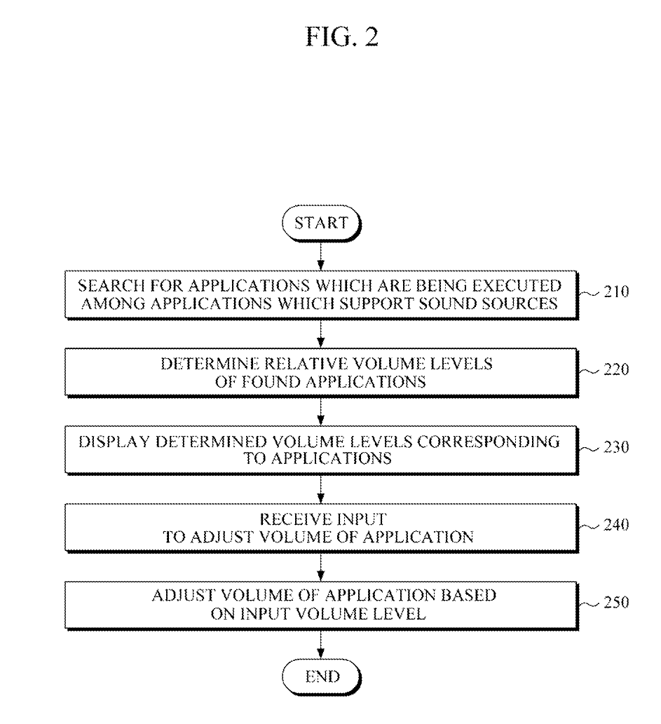

FIG. 2 is a flow chart illustrating a method for controlling volume according to an exemplary embodiment of the present invention.

Referring to FIG. 2, the method for controlling volume begins in response to receiving a command. The method for controlling volume may occur in a terminal, such as, a cellular phone, a smart phone, a computer, a tablet computer, a match, etc. In operation 210, the method searches for or determines an applications which may support or utilize sound producing sources and from among applications being executed in the terminal. The command may be received by clicking a reference key, (for example, a volume key) of a terminal, touching a reference area on a touch screen of a terminal, detecting motion in the proximity of a terminal, etc. However, the exemplary embodiments of the present invention are not limited thereto, and any mechanism by which to receive commands may be utilized.

In operation 220, relative volume levels of the found applications are determined. For example, a relative volume level of each application may be determined with respect to a main volume level of the media volume. However, exemplary embodiments of the present invention are not limited thereto and an absolute volume level may be determined.

In operation 230, the determined volume level is displayed in association with the corresponding application. The main volume level of the media volume may be displayed as well. However, exemplary embodiments of the present invention are not limited thereto and the absolute value of the volume level may be displayed in association with the corresponding application.

For example, a volume level of the found application may be displayed in a form of a volume control bar, such as, a seekbar utilized in the Android Operating System, a value, for example, by calculating the relative volume level of the application to the main volume, etc. However, the exemplary embodiments are not limited thereto, and a volume level may be displayed in various ways.

In operation 201, if no application is found which may support or utilize sound producing sources the main volume level of the media volume may be displayed operation 230.

In operation 240, a command to adjust the volume of an application is received.

For example, if volume of the application is displayed in a form of volume control bar, the input may be received by adjusting the volume control bar.

In operation 250, the volume of the application is adjusted to the input volume level received in operation 240. If the input volume level is greater than a main volume level of the media volume which is set at a time when the input volume level is received, the volume of the corresponding application may be adjusted to be at the main volume level of the media volume or lower than the main volume level. However, exemplary embodiments of the present invention are not limited thereto, and if the input volume level is greater than the main volume level of the media volume, the control unit may adjust the main volume to be at the same level as the input volume level or higher.

For example, a media volume may range from level 0 to level 10 and a main volume level of the media volume may be set to level 6 when a volume level is input through the UI unit 130. If the volume level input by the user is level 8, the control unit 140 adjusts the volume of the corresponding application to be level 6, i.e., the main volume level of the media volume. In other words, it may not be possible to adjust the volume of an application to be at a level greater than a main volume level of the media volume which is set at a time when the input volume level is received.

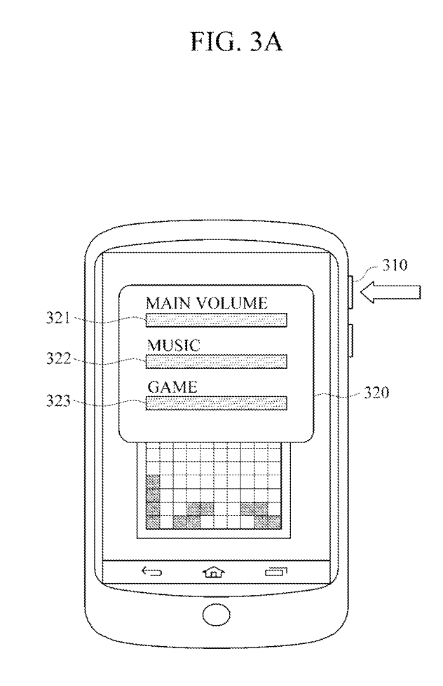

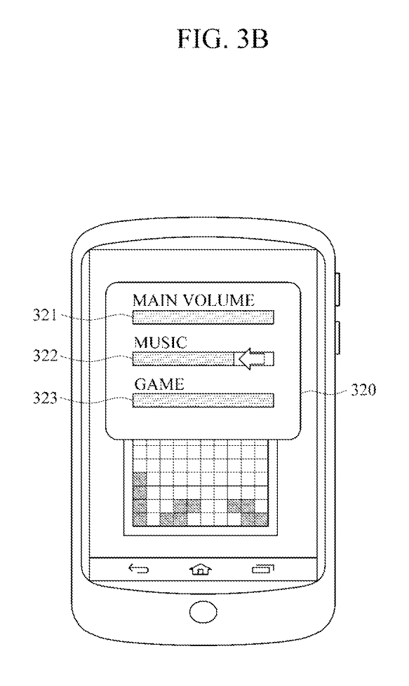

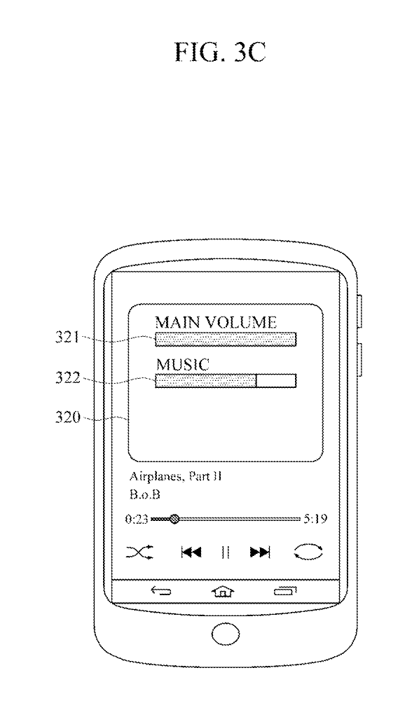

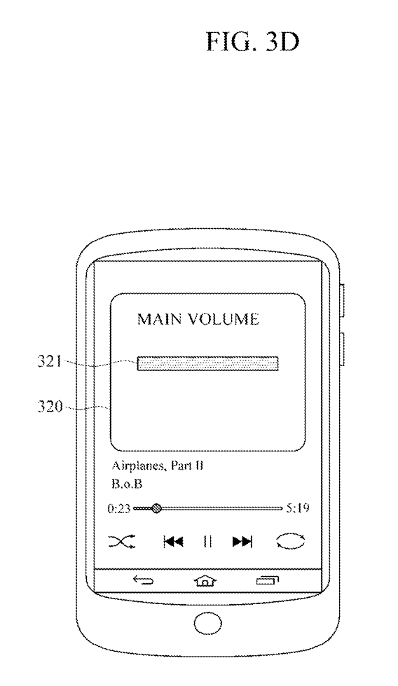

FIG. 3A, FIG. 3B, FIG. 3C, and FIG. 3D are diagrams illustrating examples of controlling volume according to an exemplary embodiment of the present invention. In FIG. 3A, FIG. 3B, FIG. 3C, and FIG. 3D, assume that a music application may be executed as a background application and a game application (for example, Tetris) may be executed as a foreground application in a terminal. Although described with reference to FIG. 1, the features of FIG. 3A, FIG. 3B, FIG. 3C, and FIG. 3D are not limited thereto.

Referring to FIG. 3A, if a user presses a volume key 310, the application searching unit 130 may detect the pressure on volume key 130 and search for or determine applications using sound. The searching unit 130 may determine the music application and the game application utilize sound and are being executed at a time when the pressure on the volume key 310 was detected. The volume level determining unit 120 may determine relative volume levels of the music application and the game applications with respect to a main volume level of the media volume. In FIG. 3A, the volume of both the music application and the game application is depicted as substantially the same volume level as that of main volume of the media volume. However, exemplary embodiments of the present disclosure are not limited thereto. The UI unit 130 may provide a volume control UI 320 in which the volume levels of the music application and the game application are displayed in the form of volume control bar 322 and volume control bar 323. The main volume level of the media volume is displayed in the form of volume control bar 321.

Although described with reference to FIG. 1 and FIG. 3A, the features of FIG. 3B are not limited thereto. Referring to FIG. 3B, if the user inputs a volume level by, for example, adjusting the volume control bar 322 of the music application, the control unit 140 adjusts the volume level of the music application to be at the volume level input by the user. In other words, in FIG. 3B, the volume level of the game application is not adjusted, but the volume level of the music application is adjusted to be at the input volume level.

Although described with reference to FIG. 1, FIG. 3A, and FIG. 3B, the features of FIG. 3C are not limited thereto. Referring to FIG. 3C, if the user terminates execution of the game application being executed in the foreground of the terminal. In FIG. 3C, the application searching unit 110 may find or determine the music application to be the only application which may support or utilize sound producing sources and is being executed by the terminal. Accordingly, the UI unit 130 displays the volume control bar 321 and volume control bar 322 corresponding to the main volume level of the media volume and the volume level of the music application, respectively.

Although described with reference to FIG. 1, FIG. 3A, FIG. 3B, and FIG. 3C, the features of FIG. 3D are not limited thereto. Referring to FIG. 3D, if the user terminates execution of the music application, no application may be found which supports or utilizes source producing sources and is being executed. Accordingly, the UI unit 130 displays on the volume control UI 320 the volume control bar 321 to control the main volume level of the media volume.

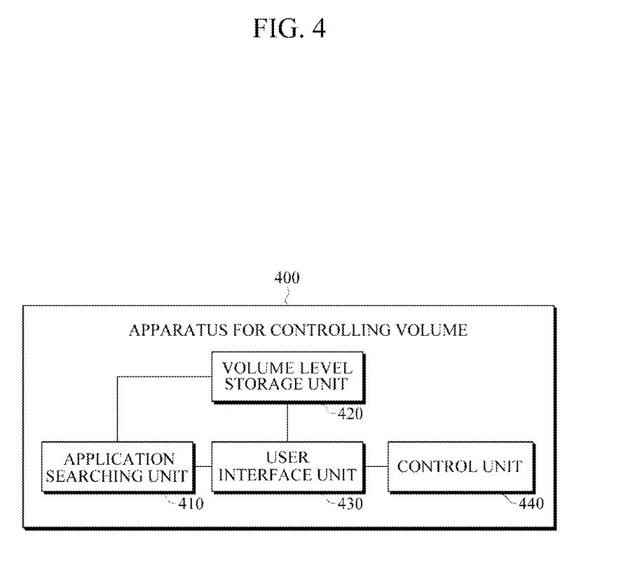

FIG. 4 is a diagram illustrating a configuration of an apparatus to control volume according to an exemplary embodiment of the present invention.

Referring to FIG. 4, the apparatus to control volume of a terminal 400 may include an application searching unit 410, a volume level storage unit 420, a user interface (“UI”) unit 430 and a control unit 440. The apparatus 400 may control the volume of a terminal. The terminal may include a media volume, which may be maximum volume of the terminal at which the terminal may operate. The media volume may include a main volume of the terminal at which the terminal is set to operate.

If a command to control volume of an application is received through a UI of a terminal, the application searching unit 410 may search for or determine applications which may utilize or support sound producing sources. A sound producing source may include any device which produces sound, such as a speaker, a bell, etc. The command may be received by clicking a reference key (for example, a volume key) of a terminal, touching a reference area on a touch screen of a terminal, performing a reference gesture in the proximity of a terminal, etc. However, the exemplary embodiments are not limited thereto, and any mechanism by which to receive commands may be utilized.

The UI unit 430 may display a list of applications found by the application searching unit 410. The UI unit 430 may display volume control bars, such as, a seekbar utilized in the Android operating system, to control volume of each of the applications found by the application searching unit 410.

The UI unit 430 may receive an input to adjust the volume of each application. For example, in order to receive the input, the UI unit 430 may display a UI as a pop-up window on a display screen of the terminal. The UI may include the list of found applications and volume control bars corresponding to each of the found application.

The volume level storage unit 420 may store the volume level, which is received by the user through the UI unit 430, in association with a corresponding application. However, exemplary embodiments are not limited thereto, and the volume level of an application may be stored independent of the application.

If the corresponding application is being executed, the control unit 440 may adjust the volume of the application to be at the volume level stored in the volume level storage unit 420. If two or more applications are being executed, the control unit 440 may adjust or determine the volume of each application to be a corresponding volume level stored in the volume level storage unit 420 for each application. However, exemplary embodiments are not limited thereto, and the control unit 440 may adjust or determine the volume level of each application to be a single volume level.

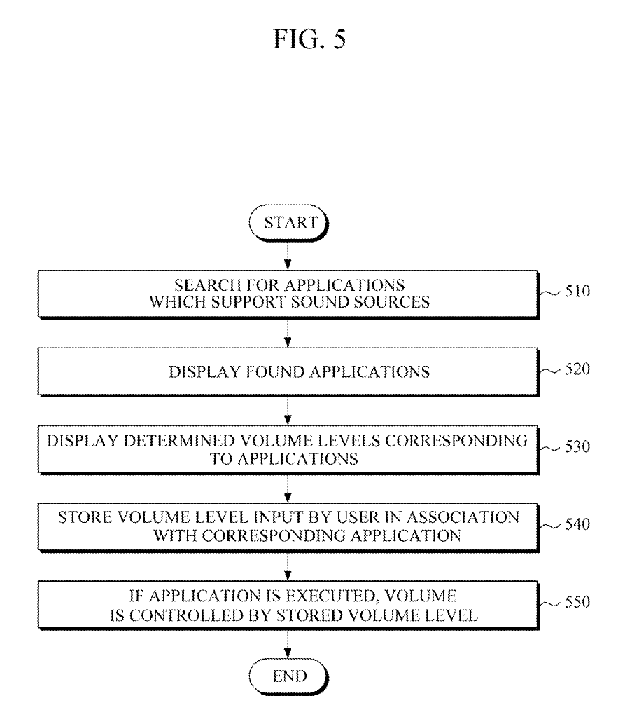

FIG. 5 is a flow chart illustrating a method for controlling volume according to an exemplary embodiment of the present invention.

Referring to FIG. 5, in operation 510, a terminal searches for or determines applications which may support or utilize sound producing sources in response to receipt of a command to control volume of the applications through a UI of a terminal. The user command to may be received by clicking a reference key (for example, a volume key) of the terminal or touching a reference area on a touch screen of a terminal, performing a reference gesture in the proximity of a terminal, etc. However, the exemplary embodiments are not limited thereto, and any mechanism by which to receive commands may be utilized.

In operation 520, a list of found applications is displayed. A volume control bar to control volume of each application may be displayed.

In operation 530, an input to control volume of each application is received. In operation 540 a input volume level is stored in association with a corresponding application. However, exemplary embodiments are not limited thereto, and the volume level of an application may be stored independent of the application.

In operation 550, if an application which may support or utilize sound producing sources is executed, the volume of the application may be controlled by the corresponding stored volume level. If two or more applications which may support or utilize sound producing sources are being executed, it may be possible to adjust or determine the volume of each application to be at a corresponding stored volume level.

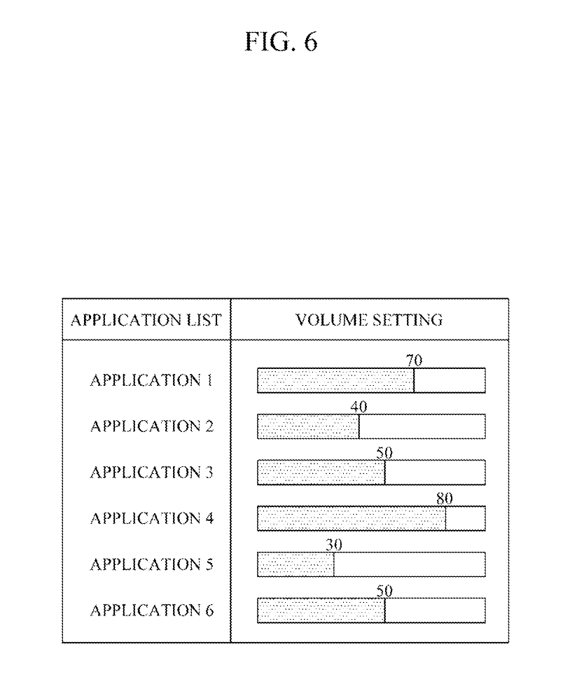

FIG. 6 is a diagram illustrating a screen of a list of applications and volume control bars displayed according to the exemplary embodiment of FIG. 4.

Referring to FIG. 6, the volume control bars to adjust the volume of applications are displayed on the right-hand side of the screen and correspond to applications displayed on the left-hand side of the screen. It may be possible to calculate a volume level of each application relative to the main volume. In FIG. 6, the relative value is displayed along with a corresponding volume control bar.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. An apparatus to control volume, comprising:
a volume level determining unit to determine the volume of an application; and
a control unit to adjust the volume of the application,
wherein a main volume of the apparatus is not changed if the application's volume is adjusted.

2. The apparatus of claim 1, further comprising:
an application searching unit to search for applications utilizing sound.

3. The apparatus of claim 1, further comprising:
a user interface unit to provide a user interface to receive input to adjust the volume of the application.

4. The apparatus of claim 1, further comprising:
a volume level determining unit to determine the relative volume of the application compared to a main volume.

5. The apparatus of claim 2, wherein the applications utilizing sound are being executed in the apparatus.

6. The apparatus of claim 1, wherein the adjusted volume level of the application is stored according to the application.

7. The apparatus of claim 6, wherein, if the application is executed, the volume of the application is controlled by the stored volume level of the application.

8. The apparatus of claim 1, wherein, if the volume of the application is adjusted to be greater than a main volume, the volume of the application is adjusted to be the same as the main volume.

9. A method for controlling volume, the method comprising:
searching for an application being executed in a terminal;
determining the volume of the executed application;
displaying the volume of the executed application;
receiving an input to adjust the volume of the executed application; and
adjusting the volume of the executed application.

10. The method of claim 9, wherein adjusting the volume of the application does not adjust a main volume of the terminal.

11. The method of claim 9, wherein the volume of two or more applications may be adjusted according to the input.

12. The method of claim 9, wherein, if the input to adjust the volume of the application is greater than a main volume of the terminal, the volume of the application is determined to be the main volume.

13. The method of claim 9, wherein the displayed volume is a relative volume with respect to a main volume level of the terminal.

14. The method of claim 9, wherein a main volume of the terminal is displayed with the volume of the application.

15. A method for controlling volume, the method comprising:
determining an application which is capable of outputting sound in a terminal;
determining the set volume of the application;
displaying the set volume of the application;
receiving an input to adjust the set volume of the application independent of a main volume of the terminal; and
storing the adjusted volume level of the application.

16. The method of claim 15, wherein if the application is executed, the volume of the application is controlled by the stored volume level of the application.

17. The method of claim 15, wherein the volume of two or more applications may be adjusted according to the input.

18. The method of claim 15, wherein, if the input to adjust the volume of the application is greater than a main volume, the stored volume level of the application is determined to be the main volume.

19. The method of claim 15, wherein the displayed set volume is a relative volume with respect to the main volume level of the terminal.
